(19) United States
(12) Patent Application Publication
(10) Pub. No.: US 2012/0242357 A1
(43) Pub. Date: Sep. 27, 2012

(54) AUTOMATIC FAULT INSERTION, CALIBRATION AND TEST SYSTEM

(75) Inventor: William N. Eccles, Tolland, CT (US)

(73) Assignee: HAMILTON SUNDSTRAND CORPORATION, Windsor Locks, CT (US)

(21) Appl. No.: 13/070,164

(22) Filed: Mar. 23, 2011

(51) Int. Cl. G01R 31/00; G01R 31/02

(52) U.S. Cl. 324/750.01; 324/537

(57) ABSTRACT

An automatic fault insertion and test (FIT) system provides an interface between a unit under test and test equipment that can be configured to allow for automatic fault insertion, testing and calibration of the test equipment. The FIT system includes an input connection terminal for connection to the UUT, an output connection terminal for connection to the test equipment and a plurality of bus circuit binding posts that can be connected to external devices. The FIT system includes a plurality of switch matrices and a plurality of common buses. Each switch matrix is connected to an input contact associated with the input connection terminal and an output contact associated with the output connection terminal, and each of the plurality of common buses. Selective control of the switches within each switch matrix allow the input contacts to be connected to the associated output contact, the input contacts to be connected to each of the four common buses, and the output contacts to be connected to each of the four common buses.

### BACKGROUND

The present invention is related to fault insertion, calibration and test of electrical equipment.

Test equipment is used to test the operation of electrical equipment, including the ability of the equipment to handle electrical faults, such as open circuits and short circuits. Fault insertion is provided by connecting faults (e.g., short-circuit faults, open-circuit faults) to the equipment being tested, referred to as the “unit under test” or UUT, and outputs are monitored. Each fault to be inserted requires manual connection of the faults to the UUT, which is a tedious and error-prone process.

In addition to fault insertion, test equipment also verifies the operation of the UUT, simulating inputs provided to the UUT and monitoring the response of the UUT. Depending on the aspect of the UUT to be tested, various outputs of the UUT are monitored, and various inputs are provided by the test equipment to the UUT. Each test operation requires manual connection of the test equipment to the UUT to accommodate the test to be performed.

To provide meaningful results the test equipment must be properly calibrated to ensure the signals provided to the UUT are proper. Calibration of the test equipment is wholly separate from testing of the UUT, and again requires manual configuration, monitoring, and measuring of various signals to ensure their accuracy.

### SUMMARY

A fault insertion, calibration and test system includes an input connection terminal, for connection to an external unit under test (UUT), an output connection terminal for connection to test equipment, and at least first and second bus circuit binding posts, each connectable to external devices. The system further includes a plurality of switch matrices, each connected to an input contact associated with the input connection terminal and an output contact associated with the output connection terminal and at least first and second common buses that connect to each switch matrix and to the bus circuit binding posts. Each switch matrix has a plurality of switches connected between the input contact, the output contact, and the common buses that are selectively configured to form connections between the input contact and the output contact, between the input contact and each of the common buses and between the output contact and each of the common buses.

### BRIEF DESCRIPTION OF THE DRAWINGS

FIGS. 1A and 1B are perspective views of the fault insertion and test system (FIT system) according to an embodiment of the present invention.

FIG. 2 is a schematic diagram of electrical connections between the FIT system, a unit under test and test equipment according to an embodiment of the present invention.

FIG. 3 is a schematic diagram illustrating the connection of switches within the FIT system according to an embodiment of the present invention.

FIGS. 4A-4H are functional diagrams illustrating various applications of the FIT system according to embodiments of the present invention.

### DETAILED DESCRIPTION

The present invention provides a system and method for interfacing units under test (UUTs) to test equipment that allows for fault insertion, a variety of different test configurations and test equipment calibration. The fault insertion, calibration and test system (referred to herein as the FIT system) includes a plurality of switches, organized into a plurality of switch matrices that allows various connections to be made between the UUT and the test equipment. In addition, the FIT system includes a plurality of common buses connected to external binding post connectors that allow for various connections to be made between the input and outputs of the UUT and test equipment and to allow for various signals to be monitored or injected into the UUT and/or the test equipment. In this way, the FIT system provides an interface that, once connected, allows electrical faults to be inserted, a plurality of testing configurations to be implemented, and test equipment to be calibrated, all without having to manually re-configure or re-connect the system.

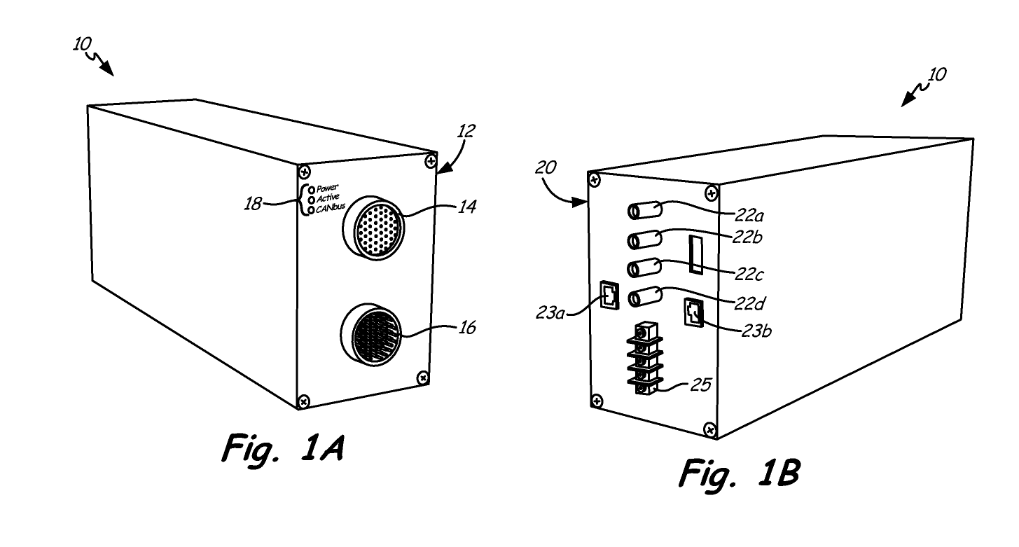

FIGS. 1A and 1B are perspective views illustrating external connections located on the front face and back face, respectively, of FIT system 10 according to an embodiment of the present invention. Front face 12 includes input connection terminal 14, output connection terminal 16, and LED indicator lights 18. Input connection terminal 14 consists of a plurality of individual socket connections or contacts (referred to subsequently as input contacts 14-1, 14-2, . . . 14-n), used to provide an interface for connecting FIT system 10 to the equipment to be tested (referred to herein as the “unit under test” or UUT, not shown). In the embodiment shown in FIG. 1A, input connection terminal 14 is a sixty-one contact connector interface commonly employed in aerospace applications, but other connection terminal configurations may be employed.

Output connection terminal 16 similarly consists of a plurality of individual pin connections or contacts (referred to subsequently as output contacts 16-1, 16-1, . . . 16-n), used to provide an interface for connecting FIT system 10 to test equipment. In the embodiment shown in FIG. 1A, output connection terminal 16 is a sixty-one contact connector interface, but in other embodiments other connection terminal configurations may be employed. In the embodiment shown in FIG. 1A, LED indicator lights 18 provide visual indications to an operator regarding the operation of FIT system 10, including indication regarding whether power is being supplied to FIT system 10, whether the system is active, and whether communications are being received and/or transmitted. In other embodiments, other visual indicators may be included depending on the application.

In the embodiment shown in FIG. 1B, back face 20 of FIT system 10 includes four bus circuit binding posts 22a, 22b, 22c, and 22d, communication interface terminals 23a and 23b, and power supply inputs 25. Bus circuit binding posts 22a-22d are connectable to a variety of electrical connectors, such as banana plugs, contact connectors, bare wire, and lug terminals. Communication interface terminals 23a, 23b provide an interface for receiving communications via a communication bus. In one embodiment, communication interface terminals are configured to communicate according to the CANbus (Controller Area Network) communication protocol. In other embodiments, other well-known communication protocols, such as Ethernet, serial data communication (e.g., RS-232, RS-422, RS-485), WiFi, IEEE-488, FireWire, etc. may be employed. In the embodiment shown in FIG. 1B, communication interface terminals 23a and 23b allow for the daisy-chain connection of FIT systems, wherein commands provided at communication interface terminal 23a are communicated to daisy-chained FIT systems (or other communication devices) via communication interface terminal 23b. Power supply inputs 25 provide an interface for receiving external power supply inputs used to power FIT system 10 (e.g., supply excitation to various switches, provide power for communications, etc.). In the embodiment shown in FIG. 1B, power supply input 25 is of screw terminal type and accepts direct current from an external power supply, not shown. In other embodiments, a connector of this or a different type may accept alternating current for use by an internal direct current power supply.

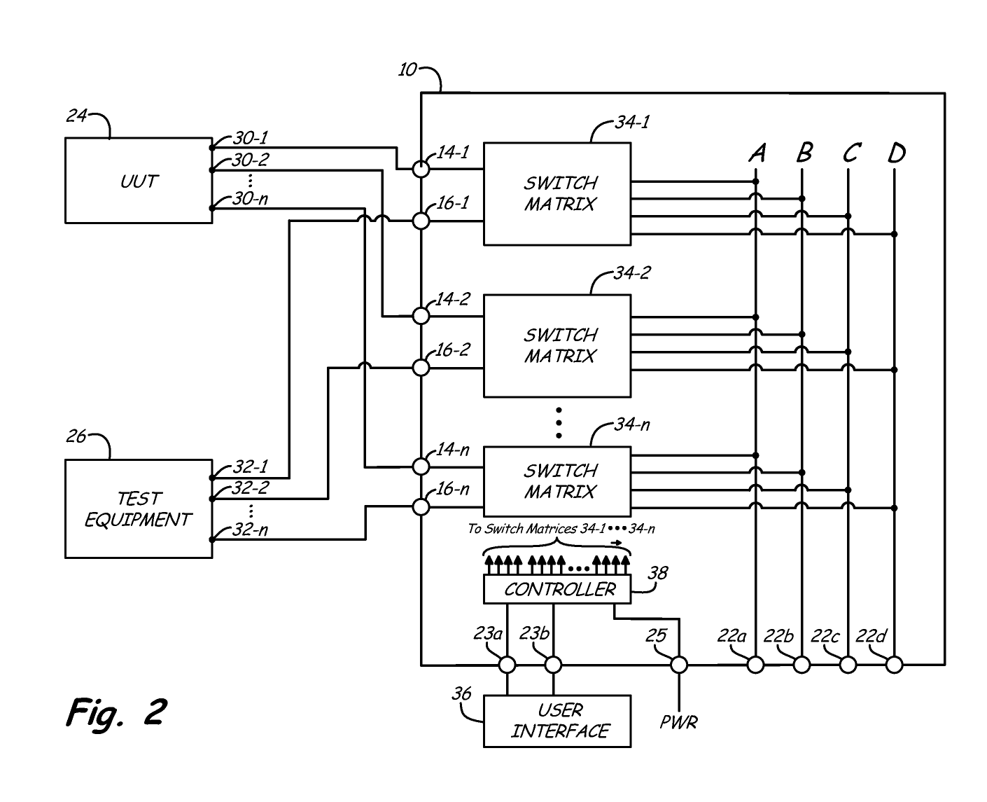

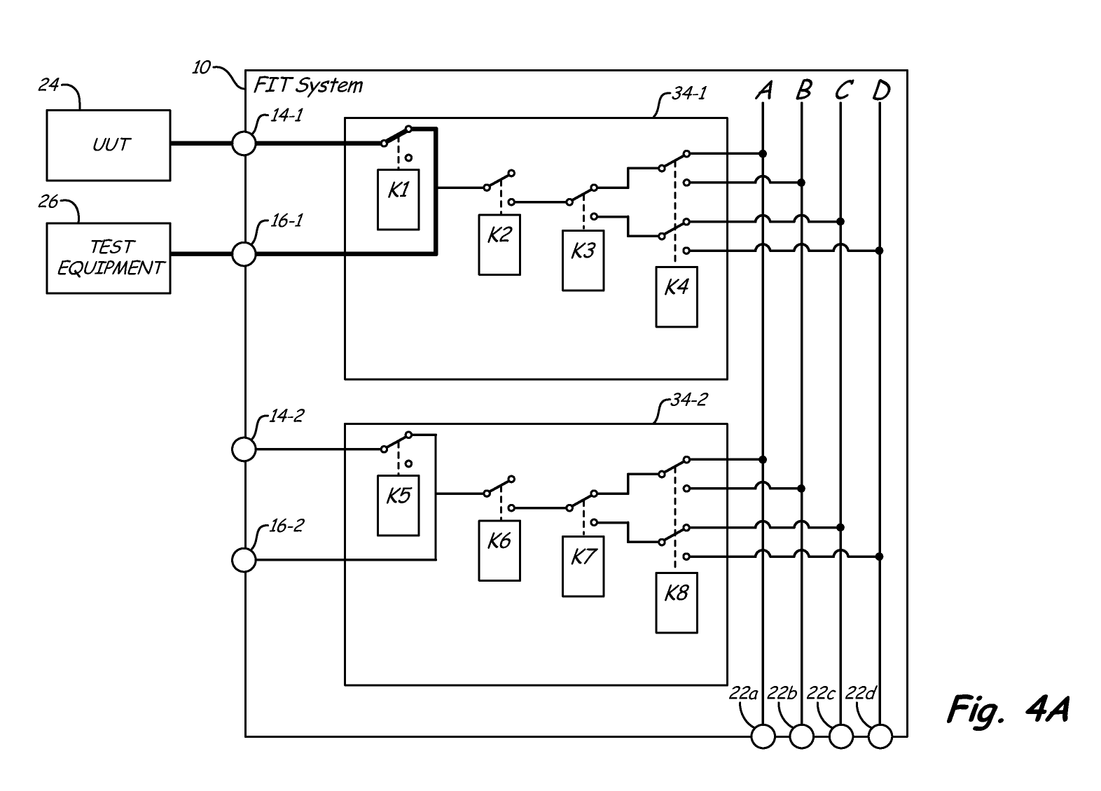

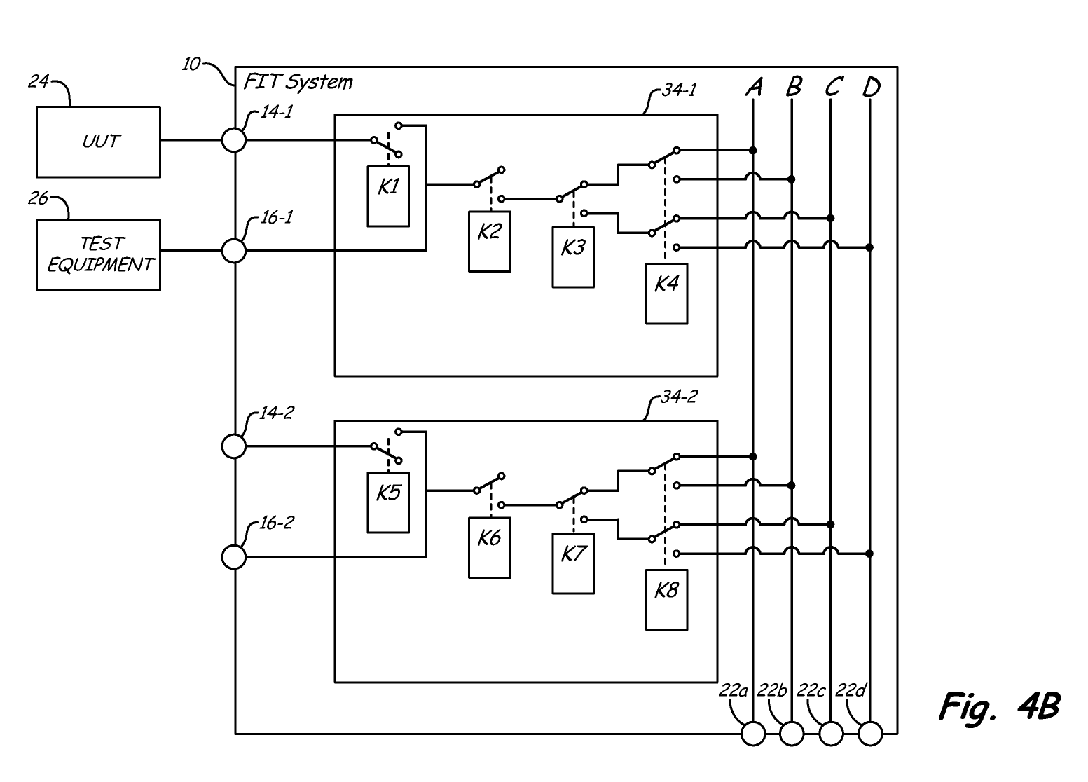

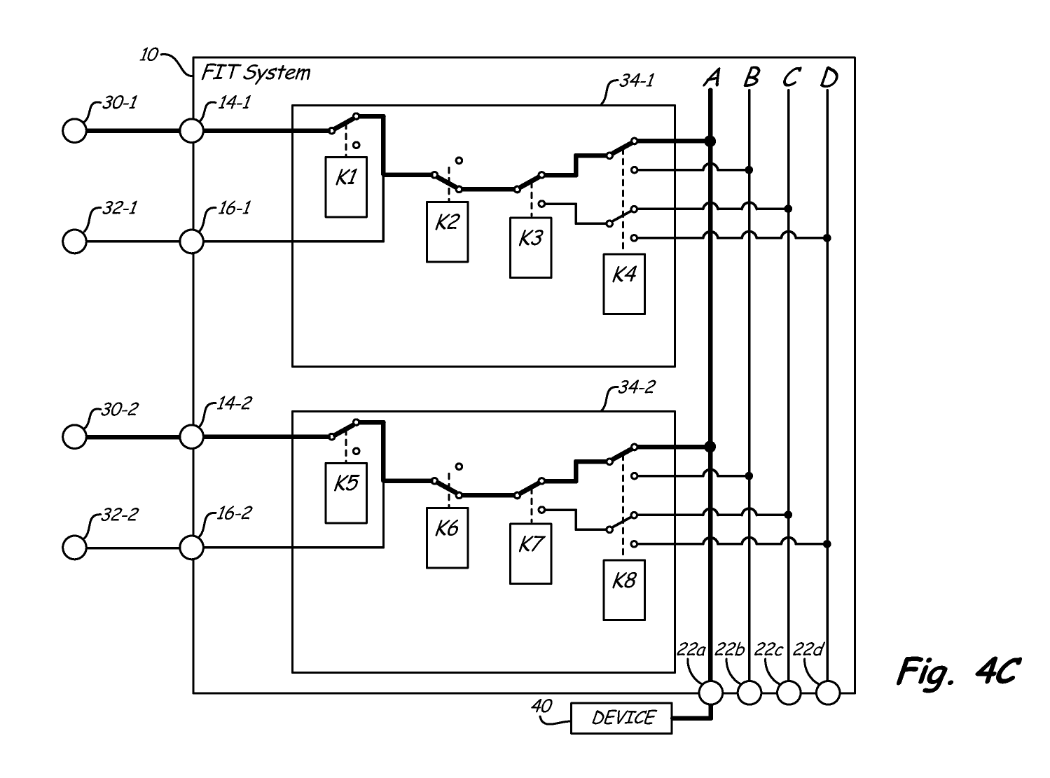

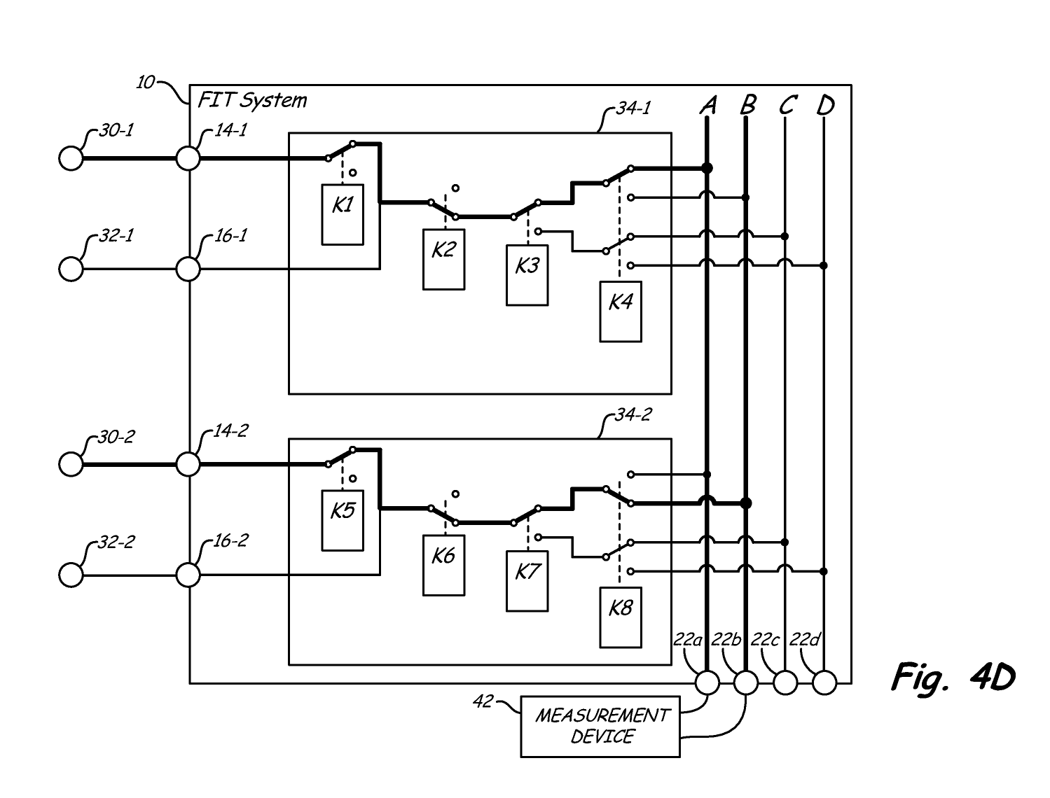

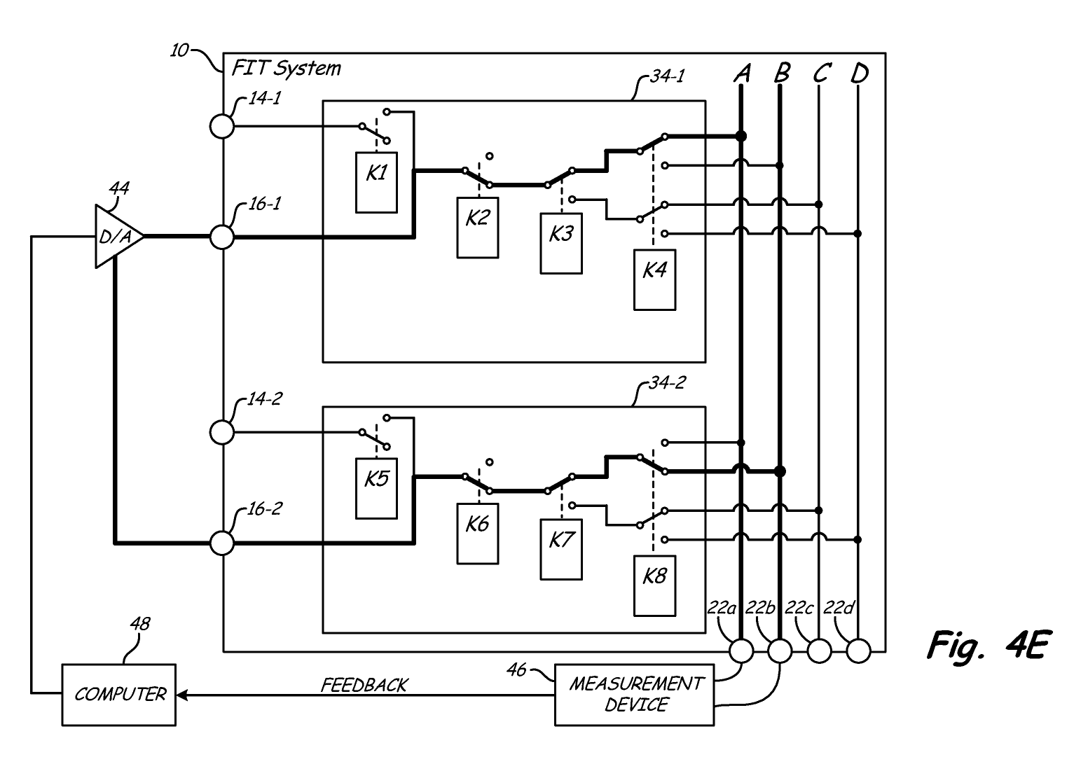

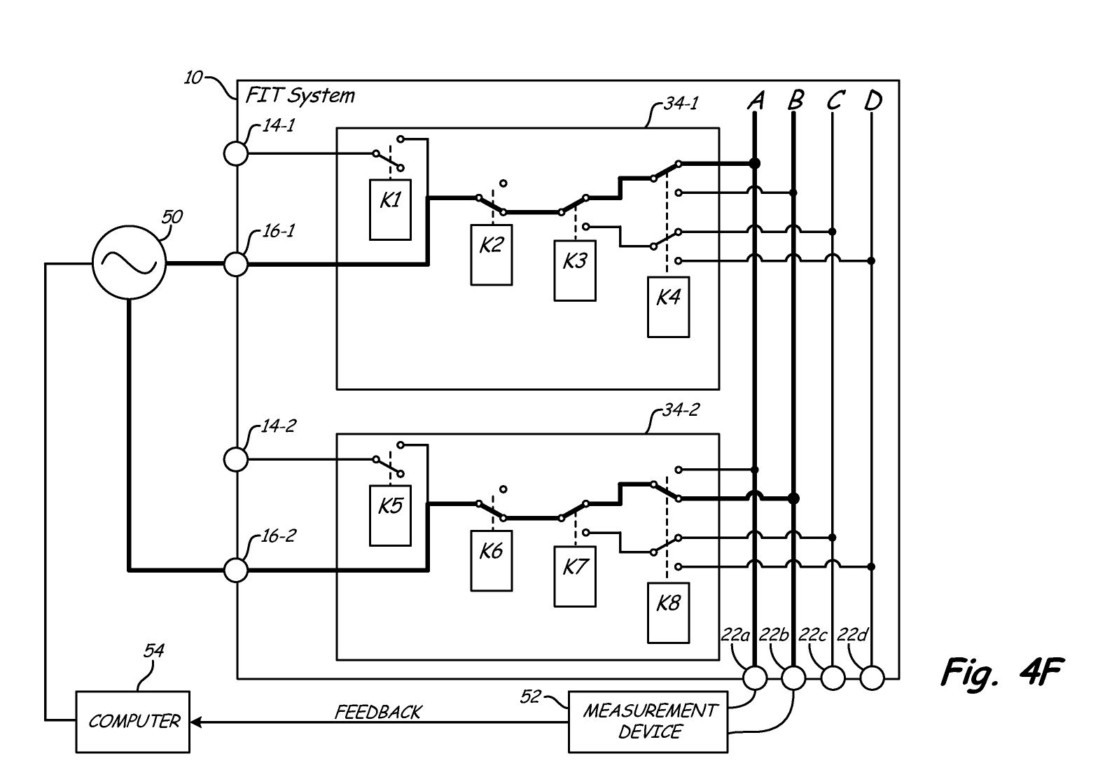

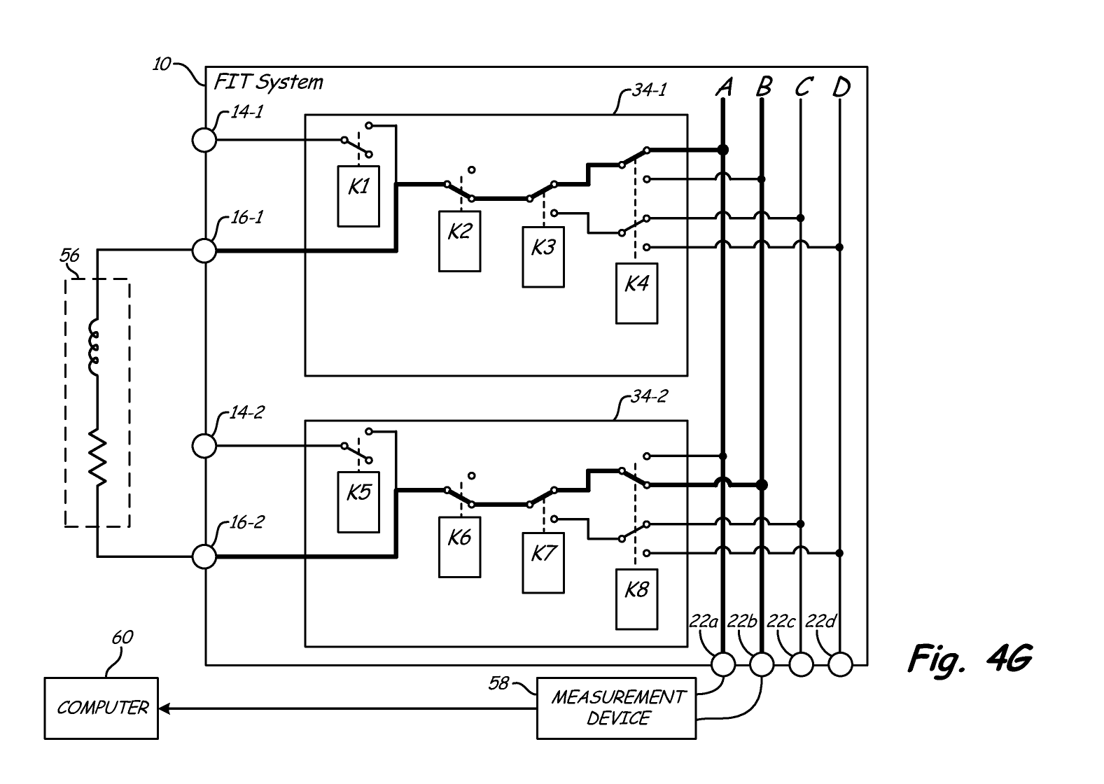

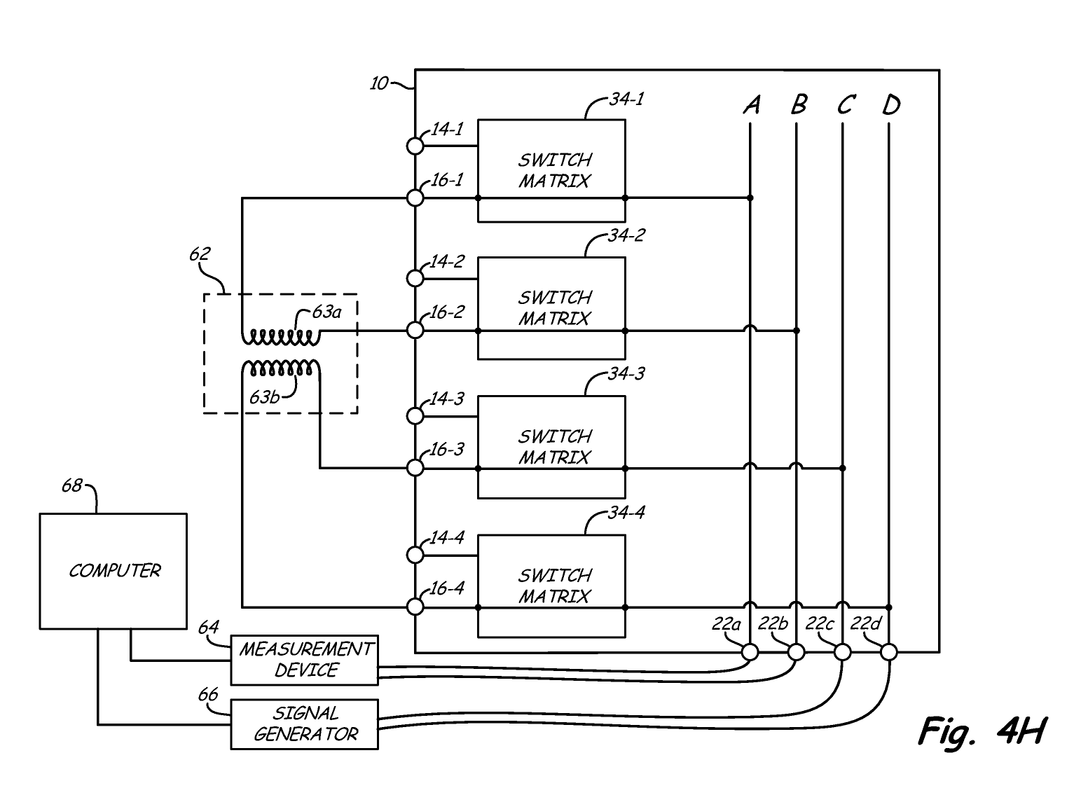

FIG. 2 is a functional block diagram illustrating the connection of UUT 24 and test equipment 26 to FIT system 10 according to an embodiment of the present invention. The embodiment shown in FIG. 2 is exemplary of one way in which FIT system 10 can be connected. However, other configurations, some of which are described with respect to FIGS. 4A-4H, are possible.

In the exemplary embodiment shown in FIG. 2, FIT system 10 is connected to UUT 24, which includes a plurality of contacts 30-1, 30-1, . . . 30-n (collectively, UUT contacts 30), via the plurality of input contacts 14-1, 14-2, . . . 14-n associated with input connection terminal 14. FIT system 10 is connected to test equipment 26, which includes a plurality of contacts 32-1, 32-2, . . . 32-n (collectively, test equipment contacts 32), via the plurality of output contacts 16-1, 16-2, . . . 16-n associated with output connection terminal 16.

In the embodiment shown in FIG. 2, FIT system 10 includes a plurality of switch matrices 34-1, 34-2, . . . 34-n (collectively switch matrices 34), each connected to one of the respective input connection terminal contacts and one of the respective output connection terminal contacts. In addition, each switch matrix is connected through common buses A, B, C, and D to bus circuit binding posts 22a, 22b, 22c, and 22d, respectively (collectively bus circuit binding posts 22). Each switch matrix 34-1, 34-2, . . . 34-n includes a plurality of individual switches that are selectively energized to form various connections between UUT contacts 30, equipment contacts 32, and common buses A, B, C, and D.

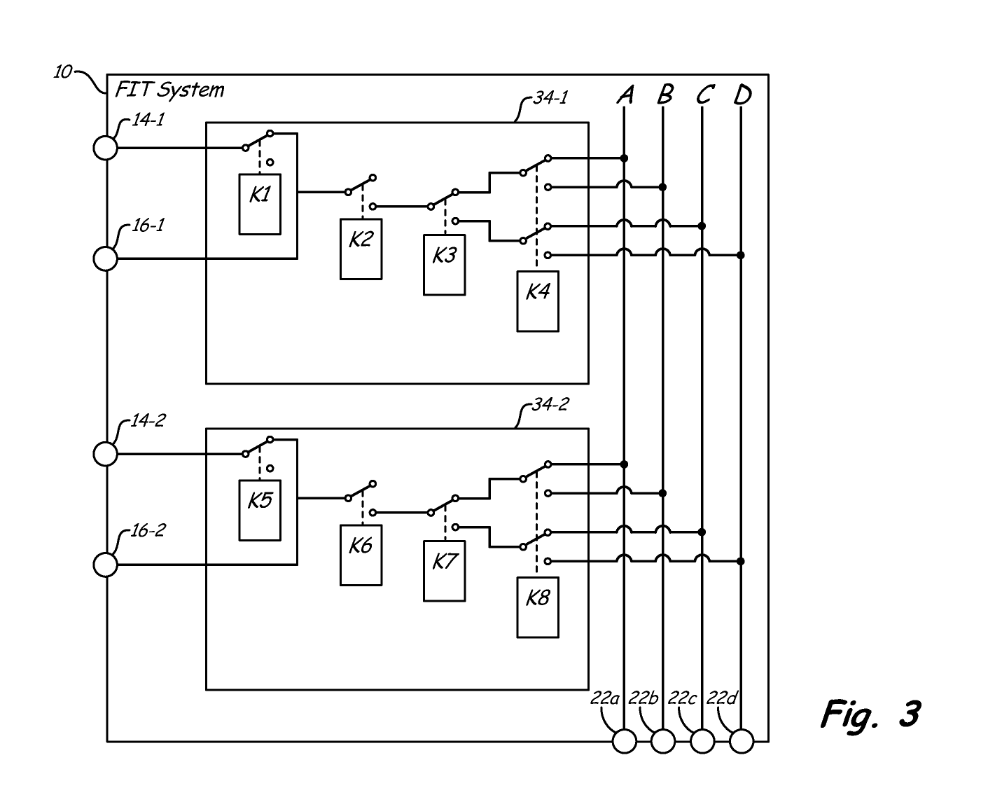

User interface 36 is connected via communication interface terminals 23a, 23b to provide control instructions to controller 38. In the embodiment shown in FIG. 1B, communication provided via user interface 36 is provided to communication interface terminal 23a and daisy-chained to other devices via communication interface terminal 23b. Through user interface 36, a technician/user provides instructions to controller 38 regarding the desired configuration of each switch within switch matrices 34-1, 34-2, . . . 34-n. Based on instructions received from user interface 36, controller 38 generates a plurality of control signals which direct the configuration of the various switches within switch matrices 34-1, 34-2, . . . 34-n. Instructions provided by user interface 36 may be provided at various levels of specificity. For example, instructions may be provided at a high-level (e.g., “execute ‘open-circuit’ test”), in which controller 38 is responsible for executing the desired test by selectively controlling switch matrices 34-1, 34-2, . . . 34-n. Conversely, user interface 36 may provide low-level instructions regarding the operation of switch matrices 34-1, 34-2, . . . 34-n, which controller 38 receives and executes by driving the plurality of switches included within the respective switch matrices 34-1, 34-2, . . . 34-n. In addition to controlling the state of switches within the plurality of switch matrices, controller 38 and/or user interface 36 enforce switching order rules, switch settle time requirements, etc. (discussed in more detail with respect to FIG. 3).

For example, selective control of switches within each switch matrix 34 allows connections to be selectively made between UUT contact 30-1 and test equipment contact 32-1, such that a signal generated by test equipment 26 at test equipment contact 32-1 is communicated to UUT contact 30-1 of UUT 24. Conversely, an output generated by UUT 24 at UUT contact 30-1 may be communicated to test equipment contact 32-1 of test equipment 26. An open circuit condition may be created between UUT contact 30-1 of UUT 24 and test equipment contact 32-1, thereby simulating an open-circuit fault for UUT 24. In addition, selective control of switches within switch matrices 34 allows the various contacts of UUT 24 and/or test equipment 26 to be selectively connected to each of the common buses A, B, C, and D associated with bus circuit binding posts 22a-22d. Depending on the application, signals may be injected via bus circuit binding posts 22a-22d into UUT 24 and/or test equipment 26, signals generated by UUT 24 and/or test equipment 26 may be monitored at bus circuit binding posts 22a-22d, or combinations thereof.

A benefit of FIT system 10, is that once connected it allows a user to connect UUT 24, test equipment 26, and devices connected to bus circuit binding posts 22a-22d in a variety of configurations through instructions provided by user interface 36, without requiring manual re-connection of various input/output terminals, etc. For example, in one configuration test equipment 26 is connected to communicate with UUT 24 through FIT system 10, without test equipment 26 being aware of the presence of FIT system 10, so that test equipment 26 can test the operation of UUT 24. Selective faults can be introduced by FIT system 10 between UUT 24 and test equipment 26, and the operation of test equipment 26 can be calibrated even while connected to UUT 24. The selection of switches to be energized is provided by an operator via communication interface terminal (e.g., communication interface terminals 23a, 23b shown in FIG. 1B).

FIG. 3 is a schematic diagram illustrating the connection of switches within FIT system 10 according to an embodiment of the present invention. In the embodiment shown in FIG. 3, switch matrix 34-1 is connected to input contact 14-1, output contact 16-1, and common bus lines (labeled A, B, C, and D) associated with bus circuit binding posts 22a-22d, respectively. Likewise, switch matrix 34-2 is connected to input contact 14-2, output contact 16-2, and common bus lines associated with bus circuit binding posts 22a-22d. Switch matrix 34-1 includes switches K1, K2, K3 and K4, and switch matrix 34-2 includes switches K5, K6, K7, and K8. Activation of switches K1-K8 is driven by controller 38 based on instructions received from user interface 36 via the communication interface terminals 23a, 23b. For the sake of simplicity, only two of the plurality of switch matrices 34 are illustrated in FIG. 3, although it should be understood that FIT system 10 may include additional switch matrices 34.

In the embodiment shown in FIG. 3, the plurality of switches are implemented with relay devices that are either energized or non-energized to provide different connections. In other embodiments, however, switches K1-K8 are implemented with solid-state devices (e.g., metal-oxide semiconductor, field-effect transistors (MOSFETs), insulated gate MOSFETs, bipolar junction transistor (BJTs), as well as other well-known switching devices) that are selectively turned On and Off to make various connections.

Each of the switches in switch matrix 34-1, 34-2 is shown in the non-energized state. Switch K1 is connected between input contact 14-1 and output contact 16-1, providing a circuit path between the two contacts in the non-energized state, and opening the circuit path between the two contacts in the energized state. Switches K2-K4 determine whether the input contact 14-1 and output contact 16-1 are connected to the common bus lines A-D, as well as the particular common bus line to which they are connected. Switch K2 is connected between the line connecting input contact 14-1 to output contact 16-1, and a plurality of switches for selective connection to one of the common bus lines. In the non-energized state, switch K2 prevents connection of either input contact 14-1 or output contact 16-1 to the common bus lines A-D. In the energized state, switch K2 provides a circuit path to one of the common bus lines, depending on the state of switches K3 and K4. Switches K3 and K4 together select the particular common bus line to which the input contact 14-1 and/or output contact 16-1 is connected. Connection is made to common bus A if both switches K3 and K4 are non-energized. Connection is made to common bus B if switch K3 is non-energized and switch K4 is energized. Connection is made to common bus C if switch K3 is energized and switch K4 is non-energized. Connection is made to common bus D if switch K3 is energized and switch K4 is energized. The connection of switches K5-K8 in switch matrix 34-2 is the same as described with respect to switch matrix 34-1.

The following table illustrates each of the possible states associated with switches K1-K4, and describes the resulting connection made as a result of the particular switch configuration. The same configuration table applies to the configuration of switches K5-K8 provided with respect to switch matrix 34-2.

TABLE 1

| | | | | | Input | | |
|---|---|---|---|---|---|---|---|
| | | | | | contact | Output | |
| | | | | | 14-1 | contatc16-1 | |
| | | | | | connected | connected | |
| Line | K1 | K2 | K3 | K4 | to: | to: | Notes |
| 1 | 0 | 0 | 0 | 0 | Output | Input | Normal |
| | | | | | contact | contact 14-1 | State |
| | | | | | 16-1 | | |
| 2 | 0 | 1 | 0 | 0 | A | A | Short to |
| | | | | | | | Bus A |
| 3 | 0 | 1 | 0 | 1 | B | B | Short to |
| | | | | | | | Bus B |
| 4 | 0 | 1 | 1 | 0 | C | C | Short to |
| | | | | | | | Bus C |
| 5 | 0 | 1 | 1 | 1 | D | D | Short to |
| | | | | | | | Bus D |
| 6 | 1 | 0 | X | X | N/C | N/C | “Open” |
| | | | | | | | fault |
| | | | | | | | condition |
| 7 | 1 | 1 | 0 | 0 | N/C | A | Out/Test |
| | | | | | | | only to Bus A |
| 8 | 1 | 1 | 0 | 1 | N/C | B | Out/Test |
| | | | | | | | only to Bus B |
| 9 | 1 | 1 | 1 | 0 | N/C | C | Out/Test |
| | | | | | | | only to Bus C |
| 10 | 1 | 1 | 1 | 1 | N/C | D | Out/Test |
| | | | | | | | only to Bus D |

Line 1 of Table 1 indicates that the normal state of each channel is with none of the switches energized, thus providing a connection from input contact 14-1 to output contact 16-1, and from input contact 14-2 to output contact 16-2. Lines 2-5 relate to states in which K2 is energized, thereby shorting input contact 14-1 and output contact 16-1 to one of the four common buses A-D. Line 6 relates to the state in which switch K1 is energized and switch K2 is non-energized, creating an open-circuit fault between input contact 14-1 and output contact 16-1 (i.e., injecting an open-circuit fault into input contact of the unit under test). Lines 7-10 relate to states in which switches K1 and K2 are energized, thereby disconnecting input contact 14-1 from the switch matrix and connecting the output contact 16-1 associated with the test equipment to one of the plurality of common buses, A-D.

As described with respect to lines 2-5, in which one or more contacts of input terminal 14 and one or more contacts of output terminal 16 are shorted to common buses A, B, C, or D, various fault conditions may be simulated. For example, simulated ground can be connected via bus circuit binding posts 22a-22d to simulate a ground fault at one of the input contacts 14 and/or output contacts 16. By connecting two or more input contacts 14-1, 14-2 to the same common bus, contact-to-contact shorts can be simulated. In addition, by connecting two or more FIT systems together via bus circuit binding posts 22-22d, multiple contact shorts on two or more UUTs may be tested. As described with respect to lines 7-10, by connecting various meters and/or signal sources to bus circuit binding posts 22a-22d, test equipment 26 can be calibrated.

When transitioning between various switching states, user interface 36 and/or controller 38 (shown in FIG. 2) may enforce switching order requirement or rules to prevent undesirable fault conditions. For example, when connecting input contacts 14-1, 14-2 or output contacts 16-1, 16-2 to common buses A, B, C or D, switches K3-K4 and K7-K8 are activated or energized first before switches K1-K2 and K5-K6 are activated or energized. In addition, when transitioning between different test configurations, switches K1-K2 and K5-K6 are typically returned to the “normal” or non-energized state before transitioning to the next configuration. As discussed above, these switching order requirements may be enforced by controller 38 or user interface 36 (or computer connected to communicate with user interface 36) depending on the application.

FIGS. 4A-4H are functional diagrams illustrating some of the plurality of applications for which FIT system 10 may be employed according to embodiments of the present invention.

FIG. 4A illustrates the “normal” condition, wherein none of the switches K1-K8 are energized and connection is provided between input contact 14-1 and output contact 16-1, and between input contact 14-2 and output contact 16-2. This is referred to as the “normal” condition because UUT 24 and test equipment 26 communicate as if they were connected directly to one another. For the sake of simplicity, UUT 24 and test equipment 26 are illustrated as connected to switch matrix 34-1, however, both UUT 24 and test equipment 26 would, in most cases, be connected to each of the switch matrices associated with FIT system 10.

FIG. 4B illustrates injection of an open-circuit condition, wherein switches K1 and K5 are energized to open the circuit path between input contact 14-1 and output contact 16-1 and between input contact 14-2 and output contact 16-2, respectively. Switches K2 and K6 remain in the non-energized state such that output contacts 16-1 and 16-2 are not connected to any of the common bus lines A-D. This mode of operation is useful for testing the response of UUT 24 in response to an open-circuit condition at one or more of the inputs of UUT 24.

FIG. 4C illustrates injection of a contact-to-contact short condition, in which switches associated with switch matrix 34-1 provide a circuit path from input contact 14-1 to common bus A (K1, K3, and K4 non-energized, K2 energized) and switches associated with switch matrix 34-2 provide a circuit path from input contact 14-2 to common bus A (K5, K7, and K8 non-energized, K6 energized). As a result, a contact-to-contact short is created between input contacts 14-1 and 14-2. This configuration is useful in providing short-circuit faults between inputs contacts (e.g., input contacts 30-1 and 30-2 in the embodiment shown in FIG. 4C). In addition, because both input contacts are short-circuited via common bus A, various signals can be provided to the shorted-together inputs, such as signals representing ground faults. In the embodiment shown in FIG. 4C, device 40 is connected to common bus A via bus circuit binding post 22a, and can be used to insert various signals or reference voltages into the short-circuited input contacts.

FIG. 4D illustrates contact-to-contact measurement between input contacts 14-1 and 14-2, in which switches associated with switch matrix 34-1 provide a circuit path from input contact 14-1 to common bus A and switches associated with switch matrix 34-2 provide a circuit path from input contact 14-2 to common bus B (K5 and K7 non-energized, K6 and K8 energized). Measurement device (e.g., multi-meter) 42 is connected across bus circuit binding posts 22a and 22b. For example, measurement device 42 can be used to measure the difference in voltage between signals provided at input contact 14-1 and 14-2, either with respect to signals generated at input contacts 14-1 and 14-2, or signals generated at output contacts 16-1 and 16-2 for provisions to input contacts 14-1 and 14-2.

FIGS. 4E-4H illustrate contact-to-contact measurements between output contacts 16-1 and 16-2 that allow for the calibration of various types of signals generated by the test equipment and provided to output contacts 16-1 and 16-2. A benefit of these topologies is it allows test equipment to be monitored and calibrated even while the UUT is connected to input contacts 14-1 and 14-2. In this way, the test equipment can be calibrated directly before testing of the UUT. In addition, an erroneous result with respect to the UUT can be quickly verified by checking the calibration of the test equipment without having to disconnect the UUT from FIT system 10.

The embodiment shown in FIG. 4E illustrates calibration of one or more digital-to-analog D/A converters 44 (associated with the test equipment) connected to provide input a voltage signal to output contacts 16-1 and/or 16-2 that is communicated via switch matrix 34-1, 34-2 to common buses A and B, respectively. Voltage measurement device 46 is connected to bus circuit binding posts 22a and 22b to measure the voltage provided by D/A converter 44. In the embodiment shown in FIG. 4E, the measured voltage is self-referenced (i.e., the voltage difference between the voltages on common bus A and on common bus B), with voltage measurement device 46 connected to measure the voltage difference between voltages provided to bus circuit binding post 22a and 22b. In other embodiments, the measured voltage at bus circuit binding post 22a may be relative to ground, wherein voltage measurement device 46 is connected to bus circuit binding post 22a and a reference ground signal. Voltage measured by measurement device 46 is provided as feedback to computer 48, which can then adjust/calibrate the voltage generated by D/A converter 44 to provide a desired voltage between output contact 16-1 and output contact 16-2.

The embodiment shown in FIG. 4F illustrates calibration of the frequency associated with signal generator 50 (i.e., frequency generator) that provides a signal to output contacts 16-1 and 16-2. The input is communicated via switch matrices 34-1 and 34-2 to common buses A and B, respectively. Frequency measurement device 52 connected to bus circuit binding posts 22a and 22b measures the frequency provided at output contacts 16-1 and 16-2, either separately (with respect to a third point, such as ground) or with respect to one another. Frequency measurement device 52 provides feedback to computer 54, which calibrates the frequency of the signal provided by signal generator 50 based on the received feedback.

The embodiment shown in FIG. 4G illustrates measurement of impedance 56 associated with the test equipment. Measurement of impedance 56 associated with the test equipment allows the test equipment to be calibrated to correctly interpret signals received from the unit under test during test operations. In the embodiment shown in FIG. 4G, impedance 56 of the test equipment is connected across output contacts 16-1 and 16-2, which are communicated via switch matrices 34-1, 34-2 to common bus A and common bus B, respectively. Measurement device 58 is connected to bus circuit binding posts 22a, 22b to measure the impedance. Depending on the type of impedance to be measured, impedance measurement device 58 may make use of either a direct current (DC) or alternating current (AC) voltage provided as an input via bus circuit binding posts 22a, 22b for communication via switch matrices 34-1, 34-2 to impedance 56. The measured impedance is provided as feedback to computer 60, which may use the measured impedance to configure test equipment to be used with the system.

The embodiment shown in FIG. 4H illustrates calibration of transformer 62. The concept of transformer calibration illustrated in FIG. 4H can be extended to other transformer-like devices, such as variable differential transformers (e.g., linear variable differential transformers (LVDTs), rotary variable differential transformers (RVDTs), etc.). For the sake of simplicity, a simple transformer device is shown here, and the details regarding the switches employed in switch matrices 34-1, 34-2, 34-3, and 34-4 have been omitted.

Transformer 62 provides an AC signal at winding 63a in response to an AC signal provided at winding 63b. Measurement of the signals generated in response to a test signal allows the test equipment to be calibrated to correctly interpret signals received from the unit under test during test operations. To this end, signal generator 66 injects a signal via bus circuit binding posts 22c and 22d that is communicated via common buses C and D, switch matrices 34-3 and 34-4 to output contacts 16-3 and 16-4, respectively. The injected signal is provided to winding 63b of transformer 62. The resulting signal generated at winding 63a is communicated via output contacts 16-1, 16-2, switch matrices 34-1, 34-2, and common buses A, B to bus circuit binding posts 22a, 22b, respectively. Measurement device 64 monitors the signal, and provides feedback to computer 68 regarding the measured signal.

In this embodiment, all four common buses are employed as part of the calibration process, with two of the common buses being employed to communicate a generated signal to output contacts of FIT system 10, and two of the common buses being employed to communicate signal received at output contacts to bus circuit binding posts.

The examples described with respect to FIGS. 4A-4H are not exclusive of the possible applications of the FIT system. In addition, although an embodiment of the FIT system has been described in which four common buses are provided, each connected to one of four bus circuit bindings posts, in other embodiments fewer or greater common buses may be employed by the FIT system. The greater the number of common buses, the greater the number of simultaneous operations may be performed. However, increasing the number of common buses increases the number of switches required within each switch matrix, thereby increasing the cost of the system.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A fault insertion, calibration and test (FIT) system comprising:
an input connection terminal that is connectable to a unit under test (UUT), the input connection terminal including at least a first input contact and a second input contact;
an output connection terminal that is connectable to test equipment, the output connection terminal including at least a first output contact and a second output contact;
at least a first and a second bus circuit binding post, each connectable to external devices;
at least a first and a second common bus connected to the first and second bus circuit binding posts, respectively;
a first switch matrix having a first plurality of switches connected between the first input contact, the first output contact, and the first and second common buses; and
a second switch matrix having a second plurality of switches connected between the second input contact, the second output contact, and the first and second common buses, wherein the first and second plurality of switches are selectively controlled to configure connections between the first and second inputs contacts, the first and second outputs contacts, and the first and second common buses.

2. The system of claim 1, wherein the first plurality of switches includes at least a first switch selectively controlled to either connect the first input contact to the first output contact or disconnect the first input contact from the first output contact.

3. The system of claim 2, wherein the first switch matrix and the second switch matrix are configured to connect the first input contact to the second input contact via either the first or second common bus.

4. The system of claim 3, wherein the first plurality of switches includes second and third switches selectively controlled to connect the first input contact to either the first common bus or the second common bus.

5. The system of claim 3, wherein the first plurality of switches includes second and third switches selectively controlled to connect the first output contact to either the first common bus or the second common bus.

6. The system of claim 5, wherein the first output contact is connectable to a signal generator and the first bus circuit binding post is connected to a measurement device, wherein the signal provided by the signal generator is communicated by the first switch matrix to the first common bus for measurement by the measurement device.

7. The system of claim 5, wherein the second plurality of switches includes fourth, fifth and sixth switches selectively controlled to connect the second output contact to either the first common bus or the second common bus.

8. The system of claim 5, wherein a load is connected between the first output contact and the second output contact, and a measurement device is connected to the first and second bus circuit binding posts, wherein the measurement device measures an impedance associated with the load.

9. The system of claim 2, wherein the first, second and third switches are relays having an energized state and a non-energized state.

10. The system of claim 2, wherein the first, second and third switches are solid-state semiconductor devices having an On state and an Off state.

11. The system of claim 1, further including:
a communication interface terminal for receiving instructions from a user via a user interface.

12. The system of claim 11, further including:
a controller that selectively controls the operation of the first and second plurality of switches included in the first and second switch matrices, respectively, based on instructions received via the communication interface terminal.

13. A fault insertion, calibration and test (FIT) system comprising:
an input connection terminal that is connectable to a unit under test (UUT), the input connection terminal including at least a first input contact and a second input contact;
an output connection terminal that is connectable to test equipment, the output connection terminal including at least a first output contact and a second output contact;
first, second, third and fourth bus circuit binding posts, each connectable to external devices;
first, second, third and fourth common buses connected to the first, second, third and fourth bus circuit binding posts, respectively;
a first switch matrix having a first plurality of switches connected between the first input contact, the first output contact, and the first, second, third and fourth common buses, the first switch matrix comprising:
a first switch connected between the first input contact and the first output contact that is selectively controlled to either connect or disconnect the first input contact from the first output contact; and
second, third and fourth switches connected between the first switch, the first output contact and the first, second, third and fourth common buses, wherein the second, third, and fourth switches are selectively controlled to connect the first input contact and/or the first output contact to one of the four common buses; and
a second switch matrix having a second plurality of switches connected between the second input contact, the second output contact, and the first, second, third and fourth common buses, the second switch matrix comprising:
a fifth switch connected between the second input contact and the second output contact that is selectively controlled to either connect or disconnect the second input contact from the second output contact; and
sixth, seventh, and eighth switches connected between the fifth switch, the second output contact and the first, second, third and fourth common buses, wherein the sixth, seventh, and eighth switches are selectively controlled to connect the second input contact and/or the second output contact to one of the four common buses.

14. The system of claim 13, wherein the first switch is controlled to create a circuit path between the first input contact and the first output contact.

15. The system of claim 13, wherein the first switch is controlled to disconnect the first input contact from the first output contact.

16. The system of claim 13, wherein a circuit path is created between the first input contact and one of the four common buses through selective control of the second, third and fourth switches.

17. The system of claim 13, wherein a circuit path is created between the first output contact and one of the four common buses through selective control of the second, third, and fourth switches.

18. The system of claim 13, wherein the first, second, third, fourth, fifth, sixth, seventh, and eighth switches are relays having an energized state and a non-energized state.

19. The system of claim 13, wherein the first, second, third, fourth, fifth, sixth, seventh, and eighth switches are solid-state semiconductor devices having an On state and an Off state.

20. The system of claim 13, further including:
a communication interface terminal for receiving instructions from a user via a user interface; and
a controller that selectively controls the operation of the first and second plurality of switches included in the first and second switch matrices, respectively, based on instructions received via the communication interface terminal.
